(19) United States
(12) Patent Application Publication
(10) Pub. No.: US 2003/0112603 A1
(43) Pub. Date: Jun. 19, 2003

(54) Thermal interface

(76) Inventors: Arlen L. Roesner, Ft Collins, CO (US); Douglas A. Fleecs, Greeley, CO (US)

Correspondence Address: HEWLETT-PACKARD COMPANY, Intellectual Property Administration, P.O. Box 272400, Fort Collins, CO, 80527-2400, US

(21) Appl. No.: 10/017,543

(22) Filed: Dec. 13, 2001

(51) Int. Cl. H05K 7/20

(52) U.S. Cl. 361/719; 165/104.33; 174/252

(57) ABSTRACT

A thermal interface in accordance with the invention comprises a carrier having opposed surfaces, a layer of a phase-change material on one of the surfaces of the carrier, and a layer of a pliable, thermal compound on the other of the surfaces of the carrier. Also disclosed is a thermal interface product that additionally comprises a removable, protective covering overlying the pliable, thermal compound layer.

There is also provided an assembly comprising a substrate, an electronic component mounted on the substrate, a heat sink, and a thermal interface interposed between a surface of the electronic component and a surface of the heat sink for transferring heat generated by the electronic component to the heat sink, the surfaces of the heat sink and the electronic component being in confronting relationship. The thermal interface comprises a carrier having opposed surfaces, a layer of a phase-change material interposed between one of the surfaces of the carrier and one of the confronting surfaces of the heat sink and the electronic component, and a layer of a pliable, thermal compound interposed between the other surface of the carrier and the other one of the confronting surfaces.

### FIELD OF THE INVENTION

The present invention pertains generally to heat transfer devices and more particularly to a multilayer thermal interface for conducting heat from a heat-dissipating electronic component to a heat sink.

### BACKGROUND OF THE INVENTION

It is well-known that many semiconductor packages, whether containing integrated circuits or individual devices such as diodes or power transistors, dissipate sufficient heat to require thermal management utilizing heat sinks. The objective of thermal management in the design of electronic component packaging is to maintain the operating temperature of the active circuit or junction side of the device low enough (for example, 110° C. or below) to prevent premature component failure.

Thermal interfaces have been developed for transferring the heat produced by a heat-dissipating electronic component to a heat sink. Such thermal interfaces may simply comprise a thin film or layer of a high conductivity material interposed between the confronting surfaces of the electronic component and heat sink. The thermal interface material may serve as a filler for improving thermal conductance by flowing into the irregularities in the confronting component/heat sink surfaces. A commonly-used thermally-conductive filler material is silicone grease which has a high thermal conductivity and, because it remains semi-liquid at room temperature, the electronic component and the heat sink may be readily separated to facilitate field servicing, component upgrades, and so forth. However, silicone grease is not favored because of the associated handling problems: it is a messy contaminant that is not easily removed from clothing or equipment.

Other filler materials in common use include thermal compounds comprising a paraffin base with additives for enhancing thermal conductivity.

Such compounds are characterized by temperature responsive phase-changes so that the compound is dry, clean and therefore easy to handle at room temperature but liquefies at elevated temperatures (albeit below the operating temperature of the electronic component) so that the material flows into the irregularities in the confronting surfaces of the heat sink and the electronic component. The disadvantage of such phase-change compounds is that when they revert to the solid state upon cooling, they tend to bond to the surfaces to which they have been applied so that separation of the electronic component and the heat sink may be difficult.

Multilayer thermal interfaces adapted to be interposed between a heat-dissipating electronic component and a heat sink are also known. One such interface, sold under the trademark THERMSTRATE®, is described in U.S. Pat. No. 5,912,805, issued Jun. 15, 1999, and titled “Thermal Interface With Adhesive”. A first version of the THERMSTRATE® interface disclosed in the '805 patent comprises a thin, thermally-conductive metal foil coated on both sides with a paraffin-base, change-of-state thermal compound. A second version of the THERMSTRATE® interface disclosed in the '805 patent comprises four layers, including a pair of metal foils sandwiched between outer layers of a paraffin-base, change-of-state compound. Both of these interface structures have the disadvantage noted above, namely, that they tend to bond to the surfaces to which they are applied, making separation of the heat sink from the electronic component difficult. Further, the four-layer version of the interface disclosed in the '805 patent is adhesively bondable to either the electronic component or the heat sink further hindering their separation. Moreover, the additional layer in the four-layer version tends to increase the thermal impedance of the interface. Nevertheless, the '805 patent is incorporated herein by reference for its teaching of various materials that may be used in the construction of multilayer thermal interfaces.

### SUMMARY OF THE INVENTION

There remains a need for a multilayer thermal interface for efficiently transferring heat away from a heat-dissipating electronic component to a heat sink that facilitates separation of the heat sink from the electronic component yet is easy to handle and has a minimum number of layers.

In accordance with one specific, exemplary embodiment of the invention, there is provided a thermal interface comprising a carrier having opposed surfaces; a layer of a phase-change material on one of the surfaces of the carrier; and a layer of a pliable, thermal compound on the other of the surfaces of the carrier.

In accordance with another specific, exemplary embodiment of the present invention, there is provided a thermal interface product that additionally comprises a removable, protective covering overlying the pliable, thermal compound layer.

Pursuant to yet another specific, exemplary embodiment of the present invention, there is provided an assembly comprising a substrate; an electronic component mounted on the substrate; a heat sink; and a thermal interface interposed between a surface of the electronic component and a surface of the heat sink for transferring heat generated by the electronic component to the heat sink, the surfaces of the heat sink and the electronic component being in confronting relationship. The thermal interface comprises a carrier having opposed surfaces; a layer of a phase-change material interposed between one of the surfaces of the carrier and one of the confronting surfaces of the heat sink and the electronic component; and a layer of a pliable, thermal compound interposed between the other surface of the carrier and the other one of the confronting surfaces.

### BRIEF DESCRIPTION OF THE DRAWINGS

The foregoing and other objects, features and advantages of the invention will be evident to those skilled in the art from the detailed description, below, taken together with the accompanying drawings, in which:

FIG. 1 is an exploded, side elevation view of an assembly comprising a heat sink, a heat-dissipating electronic component mounted on a substrate, and a multilayer thermal interface interposed between the heat sink and the electronic component, the thermal interface being constructed in accordance with a preferred embodiment of the invention;

FIG. 2 is a side elevation view, in cross section, of a thermal interface product in accordance with the invention including the thermal interface of FIG. 1;

FIG. 3 is a front elevation view, in cross section, of an alternative thermal interface product in accordance with the invention;

FIG. 4 is a front elevation view, in cross section, of the alternative thermal interface product of FIG. 3 shown seated in a shipping tray; and

FIG. 5 is a side elevation view of the product and shipping tray assemblage shown in FIG. 4.

### DETAILED DESCRIPTION OF THE PREFERRED EMBODIMENTS

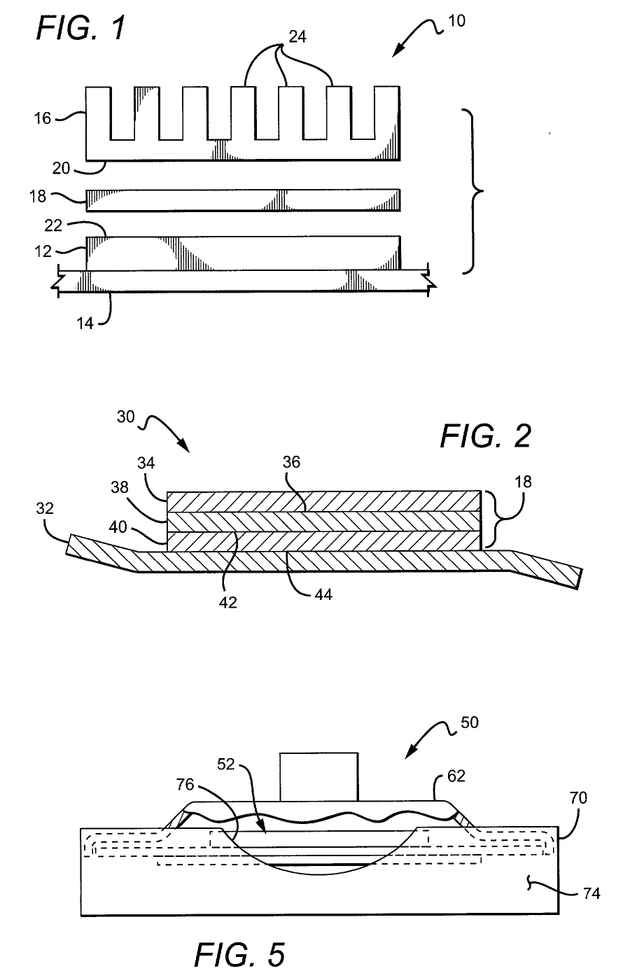

Referring to FIG. 1, there is shown an exploded view of an assembly 10 comprising a heat-dissipating electronic component 12 mounted on a substrate 14, a heat sink 16 for dissipating heat generated by the electronic component, and a thermal interface 18 constructed in accordance with the present invention adapted to be interposed between, and thermally coupling, a surface 20 of the heat sink 16 with a surface 22 of the electronic component 12.

The term “electronic component” as used herein is intended to be accorded its broadest meaning, and may comprise, without limitation, a diode, a power transistor, an integrated circuit, or any other electronic device, or a group of such devices, presently-known or developed in the future that generates heat during operation. By way of example and without limitation, the substrate 14 may comprise any presently-known or future developed electronic component support such as a circuit board in the form of a motherboard carrying one or more heat-dissipating integrated circuits including, for example, a central processing unit (CPU). The heat sink 16 may comprise any presently-known or future developed structure for dissipating heat to the surrounding environment by convection, radiation or conduction. The exemplary heat sink 16 shown in FIG. 1 is of a type commonly used, including projections or fins 24 which increase the heat-dissipating surface area of the heat sink.

With reference to FIG. 2, there is shown a thermal interface product 30 including the combination of the thermal interface 18 and a removable protective covering in the form of a backing sheet or release liner 32. The thermal interface 18 basically comprises a three-layer structure preferably die-cut or otherwise manually or automatically preformed to have a shape conforming to that of the surface 22 of the electronic component 12. A first layer 34 of the interface 18 comprises a thermally-conductive phase-change material such as a paraffin-base compound of the kind already described. Suitable commercially-available products for this purpose include HI-FLOW™ HF225UT phase-change material sold by The Bergquist Company, Chanhassen, Minn., U.S.A.; THERMFLOW® T725 phase-change material sold by Chomerics, a division of Parker Hannifin Corporation, Woburn, Mass., U.S.A.; T-pcm™ 905C phase-change material sold by Thermagon, Inc., Cleveland, Ohio, U.S.A.; and PCM45 phase-change material sold by Honeywell, Inc., San Diego, Calif., U.S.A. The phase-change material layer 34 is applied to a first surface 36 of a second thermal interface layer 38 comprising a thin, thermally-conductive metal or plastic carrier. Examples of metals that may be used for the carrier layer 38 include, without limitation, aluminum, copper, silver and gold, or alloys thereof, preferably in the form of a foil. Thermally-conductive plastics that may be utilized are also well-known and may comprise, by way of example, a heat-conducting polyimide. Other, commercially-available examples include SIL-PAD® thermally-conductive insulator material sold by The Bergquist Company, supra; CHO-THERM® thermally-conductive insulator pads sold by Chomerics, supra; and T-gon 200 SERIES™ thermally-conductive insulative pads sold by Thermagon, Inc., supra. The third layer 40 of the thermal interface 18 comprises a silicone-type grease or paste also of a kind well-known in the art, applied to a second surface 42 of the carrier 38. Examples include CHO-THERM® and THERM-A-FORM® thermally-conductive silicone compounds sold by Chomerics, supra, and DOW CORNING® 340 heat sink compound sold by Dow Corning Corporation, Midland, Minn., U.S.A. The grease layer 40 has an outer surface 44 covered by, and in contact with, the removable backing sheet or release liner 32. The liner 32 is made of a material also well-known in the art, for example, wax-coated paper or polyethylene film, and prevents exposure of the grease layer 40 during shipment and handling of the product 30. The carrier 38 provides the thermal interface 18 with structural integrity and holds the thin layers 34 and 40 of the phase-change material and grease in place.

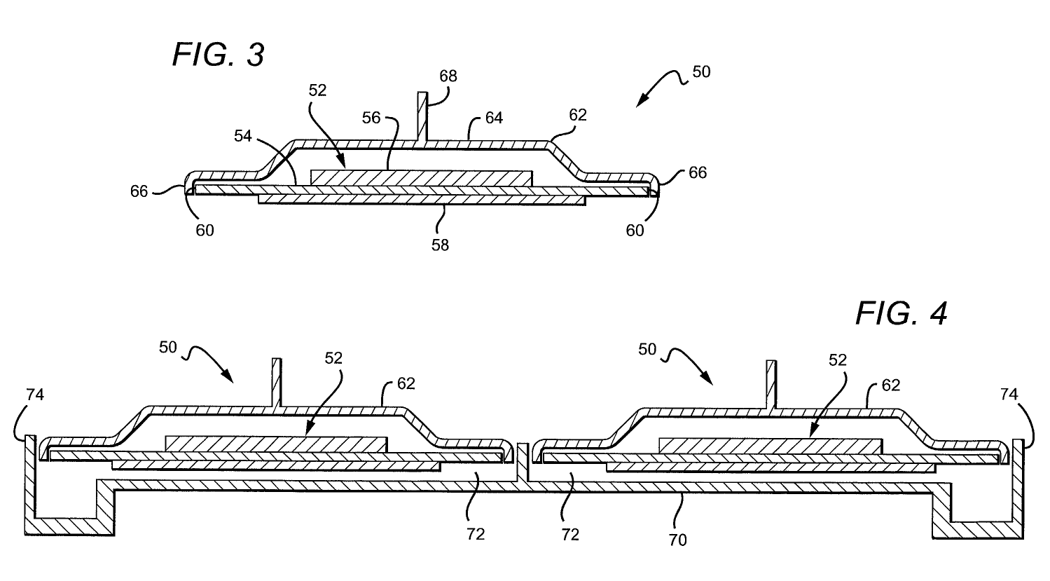

By way of example and not limitation, a manufacturer of an assembly such as that shown in FIG. 1 may separately purchase from three different suppliers the substrate 14 with the electronic component 12 mounted thereon; the heat sink 16; and the thermal interface product 30 of FIG. 2. As noted, the release liner 32 is in contact with the pliable thermal compound or silicone grease and covers it, but as seen in FIG. 3, the surface area of the liner 32 is preferably larger than that of grease layer 40. The user pulls the overhanging portion of the release liner 32 and peels it up and away from the grease layer 40. In doing so, liner 32 may remove some of the grease with it as it is removed, but the user avoids direct contact with the grease. Instead, the “contaminated” liner 32 can be easily discarded without the grease coming in contact with the user. The thermal interface 18 is then sandwiched between the confronting surfaces 20 and 22 of the heat sink 16 and the electronic component 12, respectively, with the grease layer 40 in contact with the surface 20 of the heat sink and the phase-change layer 34 in contact with the surface 22 of the electronic component. It will be obvious, of course, that the orientation of the thermal interface 18 may be reversed so that the grease layer is brought into engagement with the surface 22 of the electronic component 12.

Should disassembly be required, for example, for repair of the assembly 10, separation of the components along the pliable, that is, non-solid grease layer 40 is easily accomplished.

FIGS. 3-5 show a thermal interface product 50 in accordance with an alternative embodiment of the invention. The product 50 comprises a three layer thermal interface 52 comprising, as before, a carrier 54 having opposed surfaces one of which supports a layer 56 of thermally-conductive, silicone-type grease or paste, and the other of which receives a layer 58 of thermally-conductive phase-change material. In the embodiment of FIGS. 3-5, the carrier 54 has outer edges 60 extending outwardly beyond those of the layers 56 and 58. Instead of a thin, flexible liner that contacts the grease layer as in the first embodiment (FIG. 2), overlying the grease layer 56 in the embodiment of FIGS. 3-5 is a removable protective covering in the form of cap 62 that does not contact the grease layer. Specifically, the cap 62 includes a central, raised portion 64 spaced apart from the grease layer 56, and an outer rim 66 configured to snap over the outer edges 60 of the carrier 54. The cap 62 may also include a central lift tab 68 projecting from the raised portion 64. The cap 62 may be made of any material, including sheet metal or plastic; preferably, the cap 62 comprises a vacuum-formed, rigid or semi-rigid plastic part.

When the thermal interface 52 is ready for installation, the cap 62, which covers and protects the grease layer 56 during shipment, is preferably removed by simply pulling up on the lift tab 68. As shown in FIGS. 4 and 5, to facilitate shipment, several of the products 50 may be loaded in a tray 70 having individual compartments 72 each receiving one of the products 50. Such a tray 70 may have end walls 74 each provided with a cut out 76 to facilitate manual removal of the product 50 from the tray.

The invention combines the advantages of each of the three thermal interface materials 34, 38 and 40 while eliminating or minimizing their respective disadvantages. The invention combines the cleanliness and thermal performance of a phase-change material, the thermal performance and non-adhesion of a thermal grease, and the ease of handling a foil or film carrier. Further, the thermal interface product 30 minimizes the opportunity of a user contacting the grease, and particularly so during initial fabrication of the assembly 10. Moreover, the thermal interface 18 of the invention has only three layers thereby optimizing heat transfer from the electronic component 12 to the heat sink 16.

What is claimed is:

1. A thermal interface comprising:
a carrier having opposed surfaces;
a layer of a phase-change material on one of the surfaces of the carrier; and
a layer of a pliable, thermal compound on the other of the surfaces of the carrier.

2. The thermal interface of claim 1 in which:
the carrier comprises a thermally-conductive material.

3. The thermal interface of claim 2 in which:
the thermally-conductive material comprises a metal foil.

4. The thermal interface of claim 2 in which:
the thermally-conductive material comprises a thin, thermally-conductive plastic sheet.

5. The thermal interface of claim 2 in which:
the carrier comprises a material selected from the group consisting of copper, gold, silver, aluminum and plastic.

6. The thermal interface of claim 1 in which:
the phase-change material comprises a paraffin-base material.

7. The thermal interface of claim 1 in which:
the pliable, thermal compound comprises a thermally conductive grease.

8. The thermal interface of claim 7 in which:
the thermally-conductive grease comprises a silicone-type grease.

9. The thermal interface of claim 1 in which:
the pliable, thermal compound comprises a thermally-conductive paste.

10. A thermal interface product comprising:
a carrier having opposed surfaces;
a layer of a phase-change material on one of the surfaces of the carrier;
a layer of a pliable, thermal compound on the other of the surfaces of the carrier; and
a removable protective covering overlying the pliable, thermal compound layer.

11. The thermal interface product of claim 10 in which:
the removable protective covering comprises a peelable backing.

12. The thermal interface product of claim 10 in which:
the removable protective covering comprises a cap removably attached to the carrier.

13. The thermal interface product of claim 10 in which:
the carrier comprises a thermally-conductive material.

14. The thermal interface product of claim 13 in which:
the thermally-conductive material comprises a metal foil.

15. The thermal interface product of claim 13 in which:
the thermally-conductive material comprises a thin, thermally-conductive plastic sheet.

16. The thermal interface product of claim 13 in which:
the carrier comprises a material selected from the group consisting of copper, gold, silver, aluminum and plastic.

17. The thermal interface product of claim 10 in which:
the phase-change material comprises a paraffin-base material.

18. The thermal interface product of claim 10 in which:
the pliable, thermal compound comprises a thermally-conductive grease.

19. The thermal interface product of claim 18 in which:
the thermally-conductive grease comprises a silicone-type grease.

20. The thermal interface product of claim 10 in which:
the pliable, thermal compound comprises a thermally-conductive paste.

21. The thermal interface product of claim 11 in which:
the peelable backing comprises a release liner.

22. An assembly comprising:
a substrate;
an electronic component mounted on said substrate;
a heat sink; and
a thermal interface interposed between a surface of said electronic component and a surface of said heat sink for transferring heat generated by said electronic component to said heat sink, said surfaces of said heat sink and said electronic component being in confronting relationship, said thermal interface comprising:
a carrier having opposed surfaces;
a layer of a phase-change material interposed between one of the surfaces of the carrier and one of said confronting surfaces of said heat sink and said electronic component; and
a layer of a pliable, thermal compound interposed between the other surface of the carrier and the other one of said confronting surfaces.

23. The assembly of claim 22 in which:
the carrier comprises a thermally-conductive material.

24. The assembly of claim 23 in which:
the thermally-conductive material comprises a metal foil.

25. The assembly of claim 23 in which:
the thermally-conductive material comprises a thermally-conductive plastic sheet.

26. The assembly of claim 22 in which:
the carrier comprises a material selected from the group consisting of copper, gold, silver, aluminum and thermally-conductive plastic.

27. The assembly of claim 22 in which:
the phase-change material comprises a paraffin-base material.

28. The assembly of claim 22 in which:
the pliable, thermal compound comprises a thermally-conductive grease.

29. The assembly of claim 28 in which:
the thermally-conductive grease comprises a silicone-type grease.

30. The assembly of claim 22 in which:
the pliable, thermal compound comprises a thermally-conductive paste.
